(19) United States
(12) Patent Application Publication
(10) Pub. No.: US 2006/0032526 A1
(43) Pub. Date: Feb. 16, 2006

(54) Thermoelectric conversion material, thermoelectric conversion device and manufacturing method thereof

(75) Inventors: Kazuhiko Fukutani, Santa Cruz, CA (US); Hirokatsu Miyata, Haddano-shi (JP); Albrecht Otto, Atsugi-shi (JP); Akira Kuriyama, Atsugi-shi (JP); Miki Ogawa, Machida-shi (JP); Hiroshi Okura, Hiratsuka-shi (JP); Tohru Den, Tokyo (JP)

Correspondence Address: FITZPATRICK CELLA HARPER & SCINTO, 30 ROCKEFELLER PLAZA, NEW YORK, NY, 10112, US

(73) Assignee: CANNON KABUSHIKI KAISHA, Tokyo (JP)

(21) Appl. No.: 10/537,161

(22) PCT Filed: Dec. 12, 2003
(86) PCT No.: PCT/JP03/15951

§ 371 Date: May 31, 2005

(30) Foreign Application Priority Data
Dec. 13, 2002 (JP) 2002-363133

(51) Int. Cl. B32B 3/26; H01L 35/30; H01L 35/28

(52) U.S. Cl. 136/205; 428/304.4; 136/212

(57) ABSTRACT

A thermoelectric conversion material and a thermoelectric conversion device having a novel structure of an increased figure of merit are provided by forming nano-wires of thermoelectric material in a smaller cross-sectional size. The thermoelectric conversion material comprises nano-wires obtained by introducing a thermoelectric material (semiconductor material) into columnar pores of a porous body. The porous body is formed by providing a structure in which columns of a column-forming material containing a first component (for example, aluminum) are distributed in a matrix containing a second component (for example, silicon or germanium or a mixture of them) being eutectic with the first component, and then removing the column-forming material from the structure. The average diameter of the nano-wires of the thermoelectric material is 0.5 nm or more and less than 15 nm, and the spacing of the nano-wires is 5 nm or more and less than 20 nm.

### TECHNICAL FIELD

The present invention relates to a thermoelectric conversion material having a novel structure and a manufacturing method thereof. More particularly it relates to a thermoelectric conversion material of a novel structure that has a high thermoelectric figure of merit in a thermoelectric conversion device that converts heat to electricity or converts electricity to heat, and also to a manufacturing method thereof.

### BACKGROUND ART

It is well known that if a thermoelectric conversion material such as bismuth (Bi), bismuth telluride (BiTe) or silicon-germanium (SiGe), has a low dimensional structure such as a superlattice structure or nano-wire structure (quantum wire structure), it will have a larger thermoelectric figure of merit Z than in a bulk form (Hicks, L. D., Dresselhaus, M. S., Phys. Rev. B., Vol. 47, 12727 (1993)). One main reason of this is that low dimensional structure of the material provides a quantum effect and increases interface, which leads to a modified density of state and a modified phonon scattering without substantial change in resistivity, resulting in higher Seebeck coefficient α and lower thermal conductivity than in a bulk form. In particular, a thermoelectric material in a nano-wire form has a largely modified density of state (i.e., increase in density of state at band edge) due to the quantum effect, and hence can have a larger thermoelectric figure of merit than in a two-dimension structure such as a super-lattice structure.

The figure of merit Z that is commonly used as an index of a thermoelectric material is defined as follows:
Z=α²/χρ (1)
where α represents a Seebeck coefficient; χ represents a thermal conductivity; ρ represents a resitivity. As seen from the equation, increase in the Seebeck coefficient α or decrease in the thermal conductivity χ leads to increase in the figure of merit Z.

Accordingly, for increasing Z value, attempts have been made to produce various thermoelectric materials (semiconductor materials) in a nano-wire form (quantum wire form). For example, an attempt has been made to produce nano-wire of a thermoelectric material such as BiTe, BiSb or Bi by filling pores in a porous oxide film formed by anodization of aluminum (anodized alumina) with such a material (BiTe, BiSb or Bi) (Amy L. Prieto, Melissa S. Sander, Marisol S. Martin-Gonzalez, Ronald Gronsky, Timothy Sands, and Angelica M. Stacy “J. Am. Chem. Soc.” Vol. 123, 7160-7161 (2001)).

Here, an anodization of aluminum will be briefly described. In an anodization process of aluminum, anodizing aluminum plate or aluminum film formed on a substrate in an electrolyte acid produces porous oxide film (anodized alumina) (R C. Furneaux, W. R. Rigby & A. P. Davidson “Nature” Vol. 337, P147 (1989)). This porous oxide film is characterized by the geometrical feature that fine cylindrical pores of diameters of several nanometers to several hundred nanometers (nano-holes) are arranged in parallel at spacing of several tens nanometers to several hundred nanometers (cell sizes). Cylindrical pores those arranged at spacing of several tens nanometer or more have a high aspect ratio and relatively uniform cross sectional diameter. The diameter and spacing of the pores can be controlled to a certain degree by properly selecting the acid species and the voltage for anodization.

Thus, such anodized oxide film of aluminum can be used as a mold to produce a thermoelectric material in a nano-wire form, which will increase figure of merit Z.

However, in the anodization process of aluminum, when the anodization voltage is adjusted to form pores at spacing of 10 nm or less so as to obtain nano-wires at a high density, it is difficult to form adjacent pores separated from each other by anodized alumina wall 93 on a substrate 94 as shown in FIG. 9, that is, pores tend to communicate each other. In this situation, the anodized alumina 93 contains a more number of non-isolated pores 92 than isolated pores 91. Thus, it is difficult to produce pores separated by alumina walls with spacing of 10 nm or less, and a large area is required to produce a large number of nano-wires.

According to a theoretical calculation, the smaller the size (diameter) of nano-wire is, the greater the figure of merit Z becomes. However, the anodization of aluminum can only produce pores or nanowires of a size (diameter) of about 7 to 9 nm, and it is difficult to form pores of a cross-sectional size (or diameter) less than 7 nm. In other words, it is difficult to increase figure of merit by producing nano-wires of a cross-sectional size (diameters) of 7 nm or less.

Accordingly, it is an object of the present invention to provide a thermoelectric conversion material and a thermoelectric conversion device of a novel structure by forming nano-wires of a thermoelectric material to have a narrower size at a higher density than those conventionally fabricated, so as to increase the figure of merit Z.

It is also an object of the present invention to provide a manufacturing method to easily produce such a thermoelectric conversion material of a novel structure.

### DISCLOSURE OF THE INVENTION

A first aspect of the present invention is a thermoelectric conversion material having a multi-column structure which comprises a porous body having columnar pores and a semiconductor material that can perform thermoelectric conversion introduced into the pores of the porous body, characterized in that the porous body is formed by removing the material forming columns from a structure in which a plurality of columns of a column-forming material containing a first component are distributed in a matrix containing a second component being eutectic with the first component.

A second aspect of the present invention is a thermoelectric conversion material having a multi-column structure, characterized in that the column structure is obtained by the steps of: providing a porous body having a plurality of columnar pores, which porous body is formed by removing the material forming the columns from a structure in which a plurality of columns of a column-forming material containing a first component are distributed in a matrix containing a second component that is eutectic with the first component, introducing into the pores a semiconductor material that can perform thermoelectric conversion; and then removing the porous body.

Preferably, the porous body is a thin film.

According to the present invention, it is possible to obtain nano-wires of a thermoelectric material of which cross-sectional size and density cannot be achieved by the conventional anodization of aluminum.

According to the present invention, it is possible to obtain a structure comprising a plurality of columns and a matrix surrounding the columns, wherein the columns have a Seebeck coefficient at a room temperature larger than when the material forming columns is in a bulk solid. The present invention also provides a thermoelectricity conversion device comprising on a substrate, a structure which comprises columns of a material and a matrix surrounding the columns, wherein the columns have a Seebeck coefficient larger than that of the material in a bulk solid at room temperature, and the columns are electrically connected to electrodes; and the device generates current flow in response to thermal change of outside.

In the present invention, the porous body may be subject to a chemical treatment before the semiconductor material is introduced into the pores. The chemical treatment is desirably an oxidation treatment. Such a chemical treatment (oxidation treatment) of the porous body allows the porous body to be chemically stabilized. In some cases, the chemical treatment (oxidation treatment) can decrease the thermal conductivity of the porous body to the level lower than that of anodized alumina, thereby increase the efficiency of the resulting thermoelectric conversion device.

In the present invention, preferably the column-forming material is aluminum; the matrix is silicon; and the structure has 20 atomic % (inclusive) to 70 atomic % (inclusive) of silicon. Alternatively, preferably the column-forming material is aluminum; the matrix is germanium; and the structure has 20 atomic % (inclusive) to 70 atomic % (inclusive) of germanium.

In the present invention, the main component of the porous body is silicon or germanium or complex thereof except for oxygen. Such a composition allows formation of nano-wires of a thermoelectric material, of which density and cross-sectional size cannot be achieved by the anodization of aluminum.

The cross-sectional size of a column in the column-containing structure is desirably between 0.5 nm (inclusive) and 15 nm (inclusive). Such a cross-sectional pore size can provide a higher thermoelectric figure of merit.

The spacing of columns in the column-containing structure is desirably between 5 nm (inclusive) and 20 nm (inclusive). Such spacing can provide higher density of nano-wires of thermoelectric material.

Part of the column-forming material is desirably crystalline material, and the matrix is desirably of amorphous material.

According to one aspect of the present invention, there is provided a manufacturing method of a thermoelectric conversion material of the present invention that comprises the steps of: providing a structure in which columns of a column-forming material containing a first component are distributed in a matrix containing a second component that is eutectic with the first component: removing the column-forming material from the structure to obtain a porous body; and introducing a semiconductor material into the pores of the porous body.

The method may have a further step of removing the matrix after the introduction step. The method may also have a step of chemically treating the porous body after the removal step. The chemical treatment is desirably an oxidation treatment. The removal step is desirably etching. The introduction step is preferably electrodeposition.

The semiconductor material is typically, but not limited to, an alloy crystal composed of Bi, Sb, Te, and/or Se, such as BiSb or BiTe, and it may also be other various materials used as a thermoelectric conversion material in a bulk form, such as Si, SiGe, etc.

Investigating microstructures containing aluminum, the inventors of the present invention found that in preparation of aluminum film on a substrate by using a film deposition method in a non-equilibrium state such as sputtering, when silicon and/or germanium are added in a predetermined ratio to aluminum, multiple aluminum columns are formed in silicon or germanium or a mixture thereof in a self-organizing manner. The inventers also found that when the film containing columnar aluminum is immersed in a solution that dissolves aluminum but not silicon or germanium or a mixture thereof, a porous body can be produced of which fine cross-sectional size and high pore density cannot be achieved by anodization of aluminum.

The inventers found that oxidation treatment of the produced porous body can change the material constituting the porous body to an oxide material.

The inventors carried out an intensive study on the basis of the above findings to complete the present invention.

It is essential to use an aluminum-silicon (germanium) film in which the amount ratio of silicon (or germanium) to the total of aluminum and silicon (or germanium) is between 20 and 70 atomic %, because only in such a range, a nano-structure having multiple columns of aluminum can be formed. In other words, if the content of silicon (or germanium) is less than 20 atomic % of the total amount of aluminum and silicon (or germanium), the aluminum columns become 15 nm or more in cross-sectional size, while if the ratio of the amount of silicon (or germanium) to the sum amount of aluminum and silicon (or germanium) is more than 70 atomic %, columnar structure of aluminum cannot be identified by typical scanning electron microscopes.

Introducing a semiconductor material by electrodeposition into such a porous body composed of silicon (or silicon oxide) or germanium (or germanium oxide) can produces nano-wires with a small cross-sectional size (for example, not less than 0.5 nm and less than 15 nm) at a high density (for example, spacing not less than 5 nm and less than 20 nm). Note that the silicon (or silicon oxide) portion or the germanium (or germanium oxide) portion constituting the porous body may be removed after the formation of the nano-wires.

The structure from which the porous body is obtained (mother structure) will be described.

The mother structure used in the present invention comprises a first component and second component, in which columns (column-forming material) containing the first component are surrounded by a matrix containing the second component. In this constitution, the mother structure desirably contains the second component in a content not less than 20 atomic % and less than 70 atomic % of the total of the first component and second component.

The content, which is here referred to the ratio of the amount of the second component to the sum of the first component and second component, is preferably between 25 atomic % (inclusive) and 65 atomic % (inclusive), and more preferably between 30 atomic % (inclusive) and 60 atomic % (inclusive).

Note that the term “column-forming material” or “columns” refers to those forming substantially columnar forms, and may further contain the second component, and the matrix may further contain the first component. The column-forming material and the matrix surrounding it may contain small amounts of oxygen, argon, nitrogen and/or hydrogen.

The ratio can be determined quantitatively by, for example, inductively coupled plasma emission spectroscopic analysis. The values of the ratio described above are in atomic %. The range between 20 atomic % (inclusive) to 70 atomic % (inclusive) corresponds to the range between 20.65 wt % (inclusive) and 70.84 wt % (inclusive), with the atomic weight of Al 26.982 and the atomic weight of Si 28.086.

The first and second components are preferably a combination of materials having an eutectic point in a phase diagram of them (so called eutectic materials). Specifically the eutectic point is 300° C. or higher, and preferably 400° C. or higher. A preferable combination of the first and the second components may be a combination of Al (as the first component) and Si (as the second component), a combination of Al (as the first component) and Ge (as the second component), or a combination of Al (as the first component) and SiₓGe₁₋ₓ (0<x<1) (as the second component).

The cross-section of the column-forming material is circular or oval. In the structure, the columns are distributed in a matrix containing the second component. The cross-sectional sizes of the columns (for circular cross sections, diameters) can be controlled as a function of the composition of the structure (or the content of the second component) and the average size of them is between 0.5 nm (inclusive) and 50 nm (inclusive), and preferably between 0.5 nm (inclusive) and 20 nm (inclusive), and more preferably between 0.5 nm (inclusive) and 10 nm (inclusive). In the case of an oval or the like, the major axis is preferably between such ranges. Here, the “average size” means that which is derived, directly from or through computer image processing of, actual picture images of columnar portions observed by SEM imaging (about a range of 100 nm by 70 nm). The lower limit of the average cross-sectional size for practical use is 1 nm or larger, or several nm or larger.

The center-to-center distance of the columns, 2R is between 2 nm (inclusive) and 30 nm (inclusive), and preferably between 5 nm (inclusive) and 20 nm (inclusive), and more preferably between 5 nm (inclusive) and 15 nm (inclusive). Note that the lower limit of the center-to-center distance 2R should be determined at least such that the columns have adequate spacing so that they do not contact with each other.

The structure is preferably one in a film form, and in this case, the columns are distributed in a matrix containing the second component where the columns are substantially perpendicular to the film plane. There is no specific limitation on the thickness of the film, and the thickness may be between 1 nm and 100 μm. Considering processing time, etc., the practical thickness is between 1 nm and 50 μm. Preferably, a film of 300 nm or thicker still has columnar-containing structure.

The structure is preferably one in a film form, and may be formed on a substrate. The substrate may be, but not limited to, an insulator substrate such as quartz glass, a semiconductor substrate such as a silicon substrate, gallium arsenide substrate or indium phosphide substrate, or, if the structure can be formed on a metal substrate or a substrate (a support matrix), a flexible substrate (of polyimide, for example).

The structure can be fabricated using a film deposition method conducted in a non-equilibrium condition. Such a film deposition method is preferably sputtering, but any of other film deposition methods for forming a material in any non-equilibrium condition can be used including resistance heating evaporation, electron-beam evaporation (EB evaporation) or ion plating. In the case of sputtering, it may be magnetron sputtering, RF sputtering, ECR sputtering or DC sputtering. In the case of sputtering, the film deposition is performed typically in an argon atmosphere with a pressure in a reactor on the order of 0.01 Pa to 1 Pa. In the sputtering, two individual material targets, or a first material target and a second material targets may be used, or alternatively a material target can be used which contains the first material and second material that are sintered with a predetermined ratio.

The structure formed on a substrate is formed in the temperature of substrate between 20° C. (inclusive) and 300° C. (inclusive), and preferably between 20° C. (inclusive) and 200° C. (inclusive).

Removing the column-forming material from the structure (by wet etching or dry etching) produces a porous body that contains multiple columnar pores. The etching only has to selectively remove the column-forming material, and the etchant is preferably an acid such as phosphoric acid, sulfuric acid, hydrochloric acid or nitric acid. The pores in the porous body produced by the removal are preferably isolated from each other or not connected to each other.

The method for fabricating the porous body from the structure desirably has: a step of providing the structure containing a first component and a second component in which the column-forming material containing the first component are surrounded by a matrix containing the second component, and the structure contains the second component at such a ratio that the amount of the second component to the sum of the first component and second component being between 20 atomic % (inclusive) and 70 atomic % (inclusive); and a step of removing the column-forming material from the structure.

### BRIEF DESCRIPTION OF THE DRAWINGS

FIG. 1 is a schematic diagram of a thermoelectric conversion material according to the present invention;

FIG. 2 is a process flow chart of a manufacturing method of a thermoelectric conversion material of the present invention;

FIG. 3 is a process flow chart of another manufacturing method of a thermoelectric conversion material of the present invention;

FIG. 4 illustrates a manufacturing method of a thermoelectric conversion material according to the present invention;

FIG. 5 is a schematic diagram of a thermal conversion material of Example 1;

FIG. 6 is a schematic diagram of a thermal conversion material of Example 2;

FIG. 7 is a schematic diagram of a thermal conversion material of Example 3;

FIG. 8 is a schematic diagram of an exemplary thermoelectric conversion device employing a thermoelectric conversion material of the embodiments and examples of the present invention; and

FIG. 9 is an exemplary cross-section view of anodized alumina in the prior art with the spacing of pores being 10 nm or less.

### BEST MODE FOR CARRYING OUT THE INVENTION

Embodiments of thermoelectric conversion materials and manufacturing methods thereof according to the invention will be described with reference to the accompanied drawings.

[Structure of Thermoelectric Conversion Material]

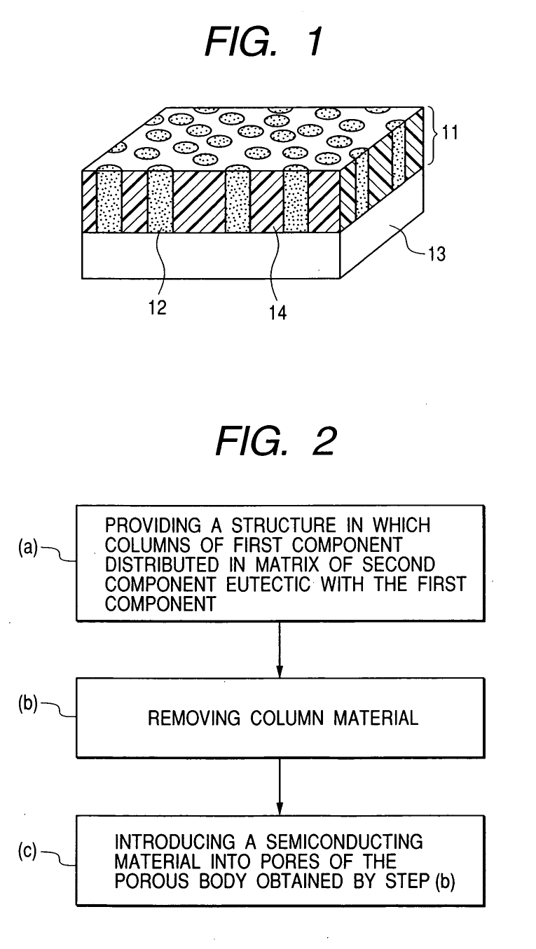

FIG. 1 is a schematic diagram of an exemplary thermoelectric conversion material according to the embodiment. In this example, a thermoelectric conversion material is shown in which quantum wires (hereinafter, referred to as nano-wires) of a thermoelectric material having cross-sectional sizes of several nm (nanometers) to several tens nm are formed in pores on a substrate. In FIG. 1, the reference numeral 11 refers to a film form of thermoelectric conversion material; the reference numeral 12 refers to thermoelectric material formed as nano-wires constituting the thermoelectric conversion material 11 (hereinafter, referred to as nano-wire(s) if necessary); the reference numeral 13 refers to a substrate; and the reference numeral 14 refers to a porous body.

The nano-wires 12 are provided in the porous body 14. As shown in FIG. 1, the nano-wires 12 are separated from each other by the porous body 14, and are provided perpendicularly or substantially perpendicularly to the substrate 13. The shape of the nano-wires 12 is columnar, as shown in FIG. 1. The diameter of the nano-wires 12 (the average diameter of nano-wires 12 viewed from the film surface) is between 0.5 nm (inclusive) and 15 nm (not inclusive), and the spacing of the nano-wires 12 (the average center-to-center distance of the nano-wires viewed from the film surface) is between 5 nm (inclusive) and 20 nm (not inclusive).

The porous body 14 constituting the thermoelectric conversion material 11 is formed by removing the column-forming material containing a first component distributed in a matrix containing a second component that is eutectic with the first component. The column-forming material containing the first component consists of, for example, a material that contains aluminum as the main component. The matrix containing the second component being eutectic with the first component, for example, germanium or silicon or a mixture of germanium and silicon.

The material of the porous body 14 preferably contains silicon (or silicon oxide) or germanium (or germanium oxide) as the main component. Alternatively, it may contain a mixture of silicon and germanium (or oxide of the mixture) as the main component. The material of the porous body 14 desirably contains silicon or germanium (or oxide thereof) as the main component, and may contain several to several tens atomic % of aluminum (Al), argon (Ar), nitrogen (N) and/or hydrogen (H).

While the material of the porous body 14 is preferably amorphous, it may contains crystalline material.

The material constituting the nano-wires is typically an alloy crystal consisting of Bi, Sb, Te and/or Se such as Bi, BiSb or BiTe, but not limited thereto. Rather, it may be any of various materials that are conventionally used as a thermoelectric conversion material in a bulk form.

In FIG. 1, the thermoelectric material 11 is not limited to the above described configuration and may have a configuration formed after removing the porous body 14 separating the thermoelectric material 12.

[Manufacturing Method of Thermoelectric Conversion Material]

Manufacturing methods of the thermoelectric conversion material according to the present invention is described below.

FIG. 2 is a process flow chart of an embodiment of the manufacturing method of the thermoelectric conversion material. The manufacturing method shown in FIG. 2 has steps (a) to (c) as follows:

(a): a step of providing a structure in which columns of a material containing a first component are distributed in a matrix containing a second component that is eutectic with the first component; then

(b): a step of removing the column-forming material from the structure to obtain a porous body; and then

(c): a step of introducing a semiconductor material into the pores of the porous body.

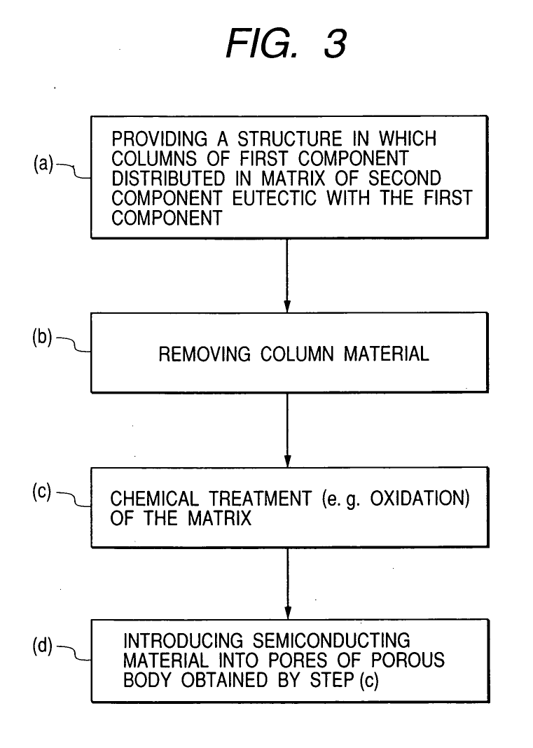

FIG. 3 is a process flow chart of another embodiment of the manufacturing method of the thermoelectric conversion material:

(a): a step of providing a structure in which columns of a material containing a first component are distributed in a matrix containing a second component that is eutectic with the first component; then

(b): a step of removing the column-forming material from the structure to obtain a porous body;

(c): a step of chemically treating (for example, oxidizing) the porous body; and then

(d): a step of introducing a semiconductor material into the pores of the porous body.

A manufacturing method of the thermoelectric conversion material will be described more specifically with reference to the drawings.

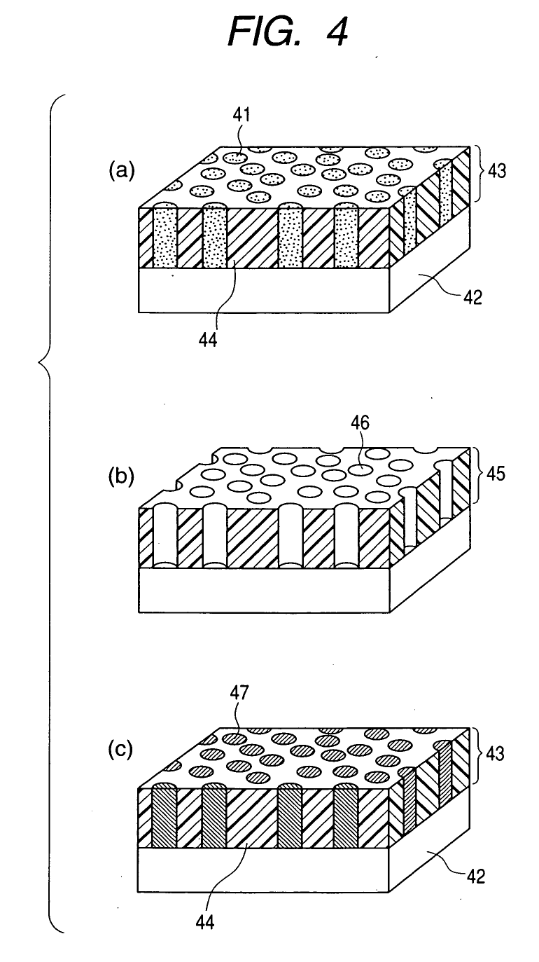

FIG. 4 illustrates an exemplary manufacturing process of a thermoelectric conversion material of this embodiment. Steps (a) to (c) are described one by one.

Step (a): A structure in which columns of a material containing a first component 41 are distributed in a matrix containing a second component 44 that can form eutectic with the first component 41 is provided.

Here, for example, aluminum (first component 41) and silicon (or germanium) (second component 44) are provided to form columns in a matrix. Then, a structured film of a mixture 43 (aluminum-silicon mixture film or aluminum-germanium mixture film) is formed on a substrate 42 by using a method such as sputtering that can produce a film in a non-equilibrium state.

When an aluminum-silicon mixture film (or aluminum-germanium mixture film) 43 is formed by using such a method, the aluminum and silicon (or germanium) form an eutectic structure in a meta-stable state in which aluminum component separates and forms a nano-structure containing multi-columns of several nm in the matrix in a self-organizing manner. Such aluminum columns are in a shape of circular cylinder of a diameter between 0.5 nm (inclusive) and 15 nm (not inclusive) and the column spacing is between 5 nm (inclusive) and 20 nm (not inclusive).

In the aluminum-silicon mixture film (or aluminum-germanium mixture film) 43, silicon (or germanium) is contained in a range of 20-70 atomic % of the total content of aluminum and silicon (or germanium) in the film and preferably between 25 and 65 atomic %, and more preferably between 30 and 60 atomic %. Silicon content in such a range allows formation of the aluminum-silicon mixture film (or aluminum-germanium mixture film) 43 in which columnar aluminum is distributed in a matrix of silicon (or germanium).

Here, the ratio of silicon to aluminum is represented by “atomic %” (atom % or at %), that is, in a ratio of the number of silicon (or germanium) atoms to that of aluminum. Such atomic % is obtained by quantitative analysis of silicon (or germanium) and aluminum in the aluminum-silicon mixture film (or aluminum-germanium mixture film) 43, for example, by using inductively coupled plasma emission spectroscopic analysis (ICP).

Step (b): Then the column-forming material is removed.

Here, for example, aluminum, the column-forming material in the aluminum-silicon mixture film (or aluminum-germanium mixture film) 43 is etched away with phosphoric acid to form pores 46 in the matrix (here, silicon or germanium). This produces a porous body 45 on the substrate 42.

The pores 46 in the porous body 45 have spacing from 5 nm (inclusive) to 20 nm (not inclusive) and its cross-sectional size is from 0.5 nm (inclusive) to 15 nm (not inclusive).

The etching solution can be a solution of an acid such as phosphoric acid, sulfuric acid, hydrochloric acid or chromic acid that dissolves aluminum but hardly dissolves silicon or germanium. However, it may be an alkaline solution such as aqueous sodium hydroxide as long as it does not have adverse-effect on the pore formation by etching, and thus should not be limited to specific types of acid or alkali. A mixture of acid solutions or alkaline solutions may also be used. The etching conditions such as solution temperature, concentration and time can be selected in a suitable manner depending on the porous body to be produced.

Step (c): A thermoelectric material (semiconductor material) 47 is introduced into the pores of the porous body produced by the removal step. Thus, the thermoelectric material 47 becomes nano-wires.

In this step, the porous body is filled with the thermoelectric material 47. For example, Bi or BiTe is filled in to pores by electrodeposition. The thermoelectric material 47 is typically BiSb or BiTe having a high thermoelectric figure of merit inherently, but not limited to them, and other various material may be used that are used as thermoelectric conversion materials in a bulk form.

The method for filling the pores with the material is preferably electrodeposition, and may also be a catalytic reaction method or VLS.

[Configuration of Thermoelectric Conversion Device]

FIG. 8 is a schematic diagram of an exemplary thermoelectric conversion device of this embodiment. Here, the “thermoelectric conversion device” means either a thermoelectric generating device that converts heat to electricity, or a thermoelectric cooling device that provides a cooling effect by the current flowing therethrough. FIG. 8 shows an example of such a thermoelectric generating device. The thermoelectric generating device of the present invention comprises a section of p-type thermoelectric conversion material 103 and a section of n-type thermoelectric conversion material 105. Either thermoelectric conversion material section comprises a plurality of nano-wires (102 or 104) and a porous body 101. FIG. 8 shows only a pair of p-type thermoelectric conversion material section 103 and n-type thermoelectric conversion material section 105. However, a typical configuration of the device has a plurality of the pairs arranged in series.

Here, a higher temperature electrode 108 and lower temperature electrodes 107 and 106 are not supported on support plates. However typical electrodes are desirably supported on a support plate.

### EXAMPLES

The present invention will be described specifically with examples.

### Example 1

In this example, a thermoelectric conversion material was produced in which the porous body having the columnar pores was amorphous silicon, and the semiconductor filled into the pores was BiTe.

First, an aluminum-silicon mixture film of about 200 nm thick containing 37 atomic % of silicon to the total of aluminum and silicon was formed by magnetron sputtering on a silicon substrate on which 20 nm of tungsten was deposited as an electrode for electrodeposition of BiTe (thermoelectric material). As a target, a six 15-mm square silicon chips are placed on a circular aluminum target of 4 inches in diameter (101.6 mm). Sputtering conditions employed were such that supply was used with an Ar flow of 50 sccm, a discharging pressure of 0.7 Pa and input power of 1 kW. The substrate temperature was room temperature (25° C.).

The aluminum-silicon mixture film thus obtained was observed by FE-SEM (Field Emission-Scanning Electron Microscope). When the surface was viewed from above at an angle, it was found that round columns of aluminum surrounded by the silicon matrix were arranged two-dimensionally as shown in (a) of FIG. 4. The diameter of the column-forming material of aluminum was 5 nm, and the average spacing (center-to-center distance) of them was 8 nm. FE-SEM observation of the cross-section shows that the columns of aluminum were isolated from each other.

Then, the aluminum-silicon mixture film thus fabricated was immerses in 98% concentrated sulfuric acid for 24 hours to selectively etch away only the column-forming material of aluminum so that pores were formed. As a result, a porous body was produced that consists of a material containing silicon as the main component except for oxygen. The surface of the pores was oxidized.

The porous body consisting of matrix containing silicon as the main component (the aluminum-silicon mixture film that had been subjected to the etching with concentrated sulfuric acid) was observed by FE-SEM. The surface viewed from above at an angle had pores surrounded by the silicon matrix, arranged two-dimensionally as shown in (b) of FIG. 4. The diameter of the pores was 5 nm, and the average spacing of them was 8 nm.

Then, BiTe (semiconductor material) was filled into the pores of the porous body containing silicon as the main component. Here, a solution of 1 mol/l nitric acid dissolving Bi and Te therein was used for electrodeposition of BiTe. The electrodeposition was performed in the solution with a reference electrode of Ag/AgCl at −1.0 V. Then, BiTe protruded from the pores were polished away.

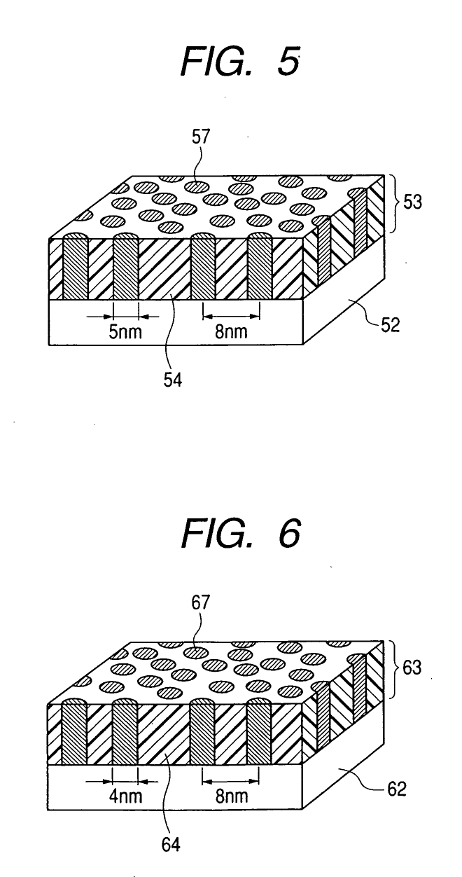

The BiTe nano-wires thus fabricated in the porous body was observed with an FE-SEM to show that the substrate surface viewed from above at an angle had BiTe nano-wires 57 arranged two-dimensionally surrounded by the porous body 54 consisting of silicon as the main component, in a thermoelectric conversion material 53 formed on the substrate 52 shown in FIG. 5. Viewed from a section, the nano-wire 57 had a form of column. The average diameter of the nano-wires 57 was 5 nm, and the average center-to-center distance of the adjacent nano-wires 57 was about 8 nm.

### Example 2

In this example, a thermoelectric conversion material was produced in which the main component of the porous body having the columnar pores was silicon oxide, and the semiconductor filled into the pores was BiTe.

First, an aluminum-silicon mixture film of about 200 nm thick containing 37 atomic % of silicon to the total of aluminum and silicon was formed by magnetron sputtering on a silicon substrate on which 20 nm of tungsten was deposited as an electrode for electrodeposition of BiTe (thermoelectric material). As a target, a six 15-mm square silicon chips are placed on a circular aluminum target of 4 inches in diameter (101.6 mm). Sputtering conditions employed were such that supply was used with an Ar flow of 50 sccm, a discharging pressure of 0.7 Pa and input power of 1 kW. The substrate temperature was room temperature (25° C.).

The aluminum-silicon mixture film thus obtained was observed with an FE-SEM (Field Emission-Scanning Electron Microscope) to find that the substrate surface viewed from above at an angle had a feature in which round columns of aluminum surrounded by the silicon matrix were arranged two-dimensionally as shown in (a) of FIG. 4. The diameter of the column-forming material of aluminum was 5 nm, and the average spacing (center-to-center distance) of them was 8 nm. FE-SEM observation of the cross-section showed that the columns of aluminum were isolated from each other.

Then, the aluminum-silicon mixture film thus fabricated was immerses in 5 wt % phosphoric acid for 7 hours to selectively etch away only the column-forming material of aluminum so that pores were formed. At the point, the silicon matrix that had been surrounding the aluminum columns was oxidized. As a result, a porous body was produced consisting of a material containing silicon oxide as the main component.

The porous body mainly consisting of silicon oxide was observed by FE-SEM. The surface viewed from above at an angle had pores surrounded by the silicon oxide matrix, arranged two-dimensionally as shown in (b) of FIG. 4. The diameter of the pores was 5 nm, and the average spacing of them was 8 nm. FE-SEM observation of the cross-section showed that the pores were isolated from each other by the matrix mainly consisting of silicon oxide.

Then, BiTe (semiconductor material) was filled into the pores of the porous body containing silicon oxide as the main component. Here, a solution of 1 mol/l nitric acid dissolving Bi and Te therein was used for electrodeposition of BiTe. The electrodeposition was performed in the solution with a reference electrode of Ag/AgCl at −1.0 V. Then, BiTe protruded from the pores were polished away.

The BiTe nano-wires thus fabricated in the porous body was observed by FE-SEM. When the surface of a thermoelectric conversion material 63 formed on the substrate 62 was viewed from above at an angle, it was shown that BiTe nano-wires 67 were arranged two-dimensionally surrounded by the porous body 64 consisting of silicon oxide as the main component, as shown in FIG. 6. From observation of a section of the substrate, the nano-wire 67 had a form of column. The average diameter of the nano-wires 67 was 4 nm, and the average center-to-center distance of the adjacent nano-wires 67 was about 8 nm.

### Example 3

In this example, a thermoelectric conversion material was produced in which the material of the porous body having the columnar pores was germanium, and the semiconductor filled into the pores was BiSb.

First, an aluminum-germanium mixture film of about 200 nm that contained 37 atomic % of germanium relative to the sum amount of aluminum and germanium was formed by magnetron sputtering, on a silicon substrate on which tungsten of 20 nm thick had been deposited thereon as the electrode for electrodeposition of BiSb (thermoelectric material). A target was used in which four 15-mm square germanium chips are placed on a circular aluminum target having a diameter of 4 inches (101.6 mm). Sputtering conditions were employed where RF power supply was used with an Ar flow: 12 sccm, a discharging pressure: 0.05 Pa and input power: 60 W. The substrate temperature was room temperature (25° C.).

The aluminum-germanium mixture film thus obtained was observed with an FE-SEM, and it was then found that the substrate surface viewed from upper side with slant had a feature in which substantially circular column-forming material of aluminum were arranged two-dimensionally while surrounded by the germanium matrix as shown in (a) of FIG. 4. The diameter of the columns of aluminum was 10 nm, and the average center-to-center distance of them was 15 nm.

Then, the aluminum-germanium mixture film that contained 37 atomic % of germanium relative to the sum amount of aluminum and germanium was immerses in 98% concentrated sulfuric acid for 24 hours to selectively etch away only the column-forming material of aluminum so that pores were formed. As the result, a porous body was produced containing germanium as the main component.

The aluminum-germanium mixture film that had been subjected to the etching with concentrated sulfuric acid (the porous body consisting of material containing germanium as the main component) was observed by FE-SEM, and it was then found that the substrate surface viewed from upper side with slant had a feature in which pores were arranged two-dimensionally while surrounded by the germanium matrix as shown in (b) of FIG. 4. The diameter of the pores, 2r was 10 nm, and the average spacing of them was 15 nm. Thus, the porous body containing germanium as the main component was produced. The fabricated sample was subjected to X-ray diffraction analysis and found to be amorphous.

Then, semiconductor material was filled into the porous body thus produced containing germanium as the main component. Here, BiSb was filled into the porous body to produce BiSb nano-wires in the porous body. Here, electrodeposition of BiSb was employed with a solution of dimethyl sulfoxide (DMSO) in which Bi(NO₃)₃.5H₂O and SbCl₃ were dissolved. The electrodeposition was performed in the solution with a reference electrode of Ag/AgCl at −1.0 V. Then, the BiSb portions protruded from the pores were polished away.

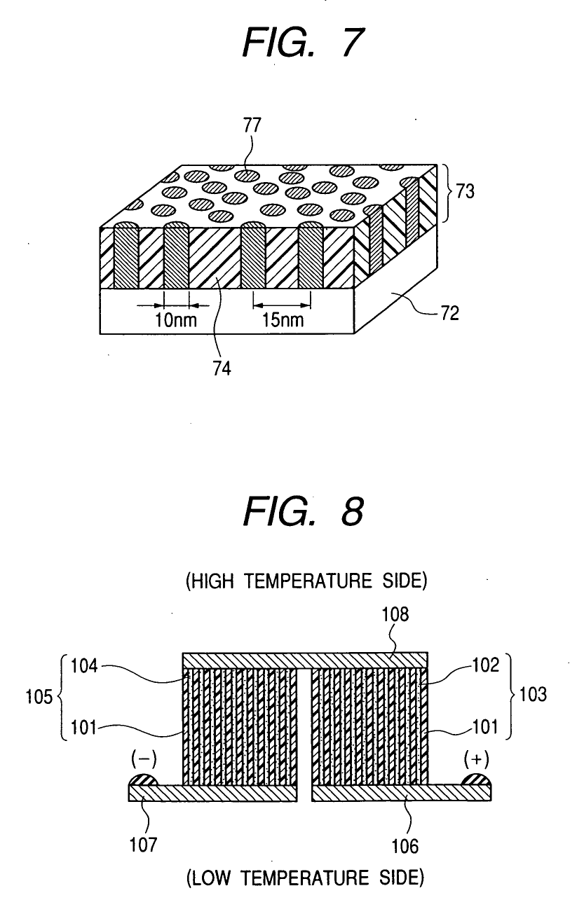

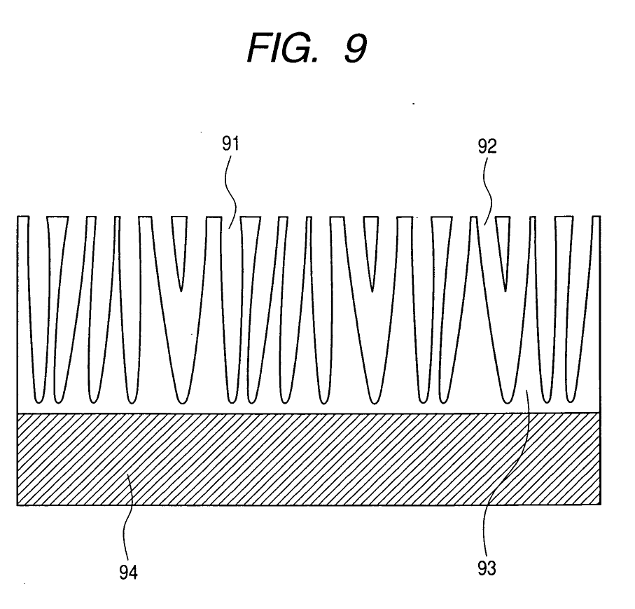

The BiSb nano-wires thus fabricated formed in the porous body was observed by FE-SEM, and it was then found that the surface viewed from upper side with slant had a feature in which BiSb nano-wires 77 were arranged two-dimensionally while surrounded by the porous body 74 containing germanium as the main component, in a thermoelectric conversion material 73 formed on the substrate 72 shown in FIG. 7. Viewed from a section of the substrate, the nano-wire 77 had a form of column. The average diameter of the nano-wires 77 was 10 nm, and the average center-to-center distance of the adjacent nano-wires 77 was about 15 nm.

As described in the above examples, according to the present invention, when semiconductor material (thermoelectric material) is filled into a porous body which is formed by providing a structure in which columns of a material containing a first component are distributed in a matrix containing a second component that can form eutectic with the first component, and then removing the column-forming material from the structure, this allows the formation of nano-wires of thermoelectric material with a diameter between 0.5 nm (inclusive) and 15 nm (not inclusive) and high density (the center-to-center distance of the nano-wires less than 20 nm).

The material constituting the porous body may be any of various materials, such as silicon or germanium.

### Example 4

In this example, a thermoelectric generating device was produced in which BiTe was employed as an n-type thermoelectric material and BiSb was used as a p-type thermoelectric material.

First, an aluminum-silicon mixture film of about 2 μm that contained 50 atomic % of silicon relative to the sum amount of aluminum and silicon was formed by magnetron sputtering, on a silicon substrate having silicon oxide surface (a support plate) on which 20 nm of tungsten had been deposited. Then, the aluminum-silicon mixture film that contained 50 atomic % of silicon relative to the sum amount of aluminum and silicon was immerses in 5 wt % phosphoric acid for 8 hours to selectively etching only the column-forming material of aluminum so that pores were formed. As the result, a porous body was produced that consists of material containing silicon oxide as the main component. Then, BiTe (n-type thermoelectric material) was electrodeposited. Then, patterns of resist were formed by photolithography, and patterns of the n-type thermoelectric conversion material were generated by dry etching. Using similar process steps, BiSb (p-type thermoelectric material) was electrodeposited on the porous body and the silicon substrate with silicon oxide (a support plate) with 20 nm of tungsten deposited thereon; patterns of resist were formed by photolithography; and patterns of the p-type thermoelectric conversion material were generated by dry etching. The silicon substrate with silicon oxide on which p-type thermoelectric material is formed, and the silicon substrate with silicon oxide on which n-type thermoelectric material is formed are attached together to form a thermoelectric conversion device, as shown in FIG. 8.

A thermoelectric conversion material employing a thermoelectric conversion material obtained by the above embodiments and examples will be described with reference to FIG. 8. A thermoelectric conversion device shown in FIG. 8, like known thermoelectric conversion devices in bulk form, is used for: a device such as a cooler or thermal controller, which performs both cooling and heating where current flowing through a material causes heat generation at one end of the material and heat absorption at the other end because of Peltier effect; and a device such as thermoelectric generator, which generate electromotive force (thermoelectromotive force) by providing a temperature difference across a material (this is the opposite effect to that of the above one).

In FIG. 8, the thermoelectric conversion device is embodied as an unit composing of multiple devices (π-type devices) connected in series with each π-type device consisting of: a thermoelectric conversion material section 103 having nano-wires 102 of p-type semiconductor material (thermoelectric material) formed in a porous body 101 (hereinafter, referred to as “p-type material section” 103); and a thermoelectric conversion material section 105 having nano-wires 104 of n-type semiconductor material (thermoelectric material) formed in a porous body 101 (hereinafter, referred to as “n-type material section”) 105. In FIG. 8, reference numeral 106 refers to an electrode provided on one end of the p-type material section 103 (hereinafter, referred to as lower temperature-side); reference numeral 107 refers to an electrode provided on one end of the n-type material section 105 (hereinafter, referred to as lower temperature-side); and reference numeral 108 refers to an electrode provided on the other ends of the material sections 103 and 105.

In the case where the thermoelectric conversion device is applied to a device that uses such an device as a thermoelectric generating device, a plurality of the ℏ-type devices of FIG. 8 are connected in series. Temperature difference between the upper electrode 108 and the lower electrodes 106 and 107 can cause the generation of electric power. Here is illustrated the case where the upper electrode 108 is in a higher temperature while the lower electrodes is in a lower temperature, thereby generating electromotive force between the lower electrodes 106 and 107 with the lower electrode 106 being positive and the lower electrode 107 being negative. The thermoelectric conversion device can also be used as a cooling device, in which the electrode 106 is connected to a negative terminal of a power supply and the electrode 107 is connected to a positive terminal of the power supply, and current flowing therethrough can cause heat absorption from the upper electrode 108 in FIG. 8. Thus, cooling around the upper electrode 108 can be performed. Such a thermoelectric conversion device can have a higher thermoelectric conversion figure of merit Z than conventional thermoelectric conversion devices.

Note that the present invention is not limited the embodiments, examples and applications illustrated above, but those skilled in the art can vary and modify them based on the description of the claims without departing from the gist of the present invention. Such variations and modifications are also in the scope of the present invention.

As described in the above examples, according to the present invention, when semiconductor material (thermoelectric material) is filled into a porous body which is formed by providing a structure in which columns of a material containing a first component are distributed in a matrix containing a second component that can form eutectic with the first component, and then removing the column-forming material from the structure, this allows the formation of nano-wires of thermoelectric material with a diameter between 0.5 nm (inclusive) and 15 nm (not inclusive) and high density (the spacing of the nano-wires less than 20 nm). A thermoelectric conversion device employing such thermoelectric conversion device can also be provided. The present invention can also provide a production method allowing easy production of the thermoelectric conversion device.

1. A thermoelectric conversion material having a multi-column structure comprising a porous body having columnar pores and a semiconductor material that can perform thermoelectric conversion introduced into the pores of the porous body, characterized in that the porous body is formed by removing a column-forming material containing a first component from a structure in which a plurality of columns of the column-forming material are distributed in a matrix containing a second component that is eutectic with the first component.

2. A thermoelectric conversion material having a multi-column structure, characterized in that the column structure is obtained by:
providing a porous body having a plurality of columnar pores which is formed by removing from a structure in which a plurality of columns of a column-forming material containing a first component are distributed in a matrix containing a second component that can form an eutectic with the first component,
introducing into the pores a semiconductor material that can perform thermoelectric conversion; and then
removing the porous body.

3. The thermoelectric conversion material according to claim 1, wherein the porous body is in a thin film.

4. The thermoelectric conversion material according to claim 1, wherein the multi-column structure is obtained by further chemically treating the porous body and then introducing the semiconductor material into the pores.

5. The thermoelectric conversion material according to claim 4, wherein the chemical treatment is an oxidation treatment.

6. The thermoelectric conversion material according to claim 1, wherein the first component is aluminum; the second component is silicon; and the structure contains silicon at 20 atomic % or more and 70 atomic % or less.

7. The thermoelectric conversion material according to claim 1, wherein the first component is aluminum; the second component is germanium; and the structure contains germanium at 20 atomic % or more and 70 atomic % or less.

8. The thermoelectric conversion material according to claim 1, wherein a main component of the porous body other than oxygen component is silicon.

9. The thermoelectric conversion material according to claim 1, wherein a main component of the porous body other than oxygen is germanium.

10. The thermoelectric conversion material according to claim 1, wherein the average diameter of columns in the structure is 0.5 nm or more and 15 nm or less.

11. The thermoelectric conversion material according to claim 1, wherein the average spacing of columns in the structure is 5 nm or more and 20 nm or less.

12. The thermoelectric conversion material according to claim 1, wherein part of the column-forming material is a crystalline material, and the matrix is an amorphous material.

13. A thermoelectric conversion device using a thermoelectric conversion material according to claim 1.

14. A manufacturing method of a thermoelectric conversion material comprising the steps of:
providing a structure in which a plurality of columns of a column-forming material containing a first component are distributed in a matrix containing a second component that is eutectic with the first component;
removing the column-forming material to form a porous body; and
introducing a semiconductor material into pores of the porous body.

15. The manufacturing method according to claim 14, comprising a step of chemically treating the porous body after the removal step.

16. The manufacturing method according to claim 14, wherein the chemical treatment is an oxidation treatment.

17. The manufacturing method of thermoelectric conversion material according to any one of claim 14 to 16, wherein the introduction step of the semiconductor is electrodeposition.

18. A structure comprising a plurality of columns of a column-forming material and a matrix surrounding the columns, wherein the columns have a Seebeck coefficient at a room temperature larger than that of the material in bulk solid.

19. The structure according to claim 18 wherein the columns are placed on a substrate, and substantially perpendicular to a surface of the substrate.

20. A thermoelectricity conversion device comprising on a substrate, a structure which comprises columns of a column-forming material and a matrix surrounding the columns, wherein the columns have a Seebeck coefficient larger than that of the material in a bulk solid at room temperature, and the columns are electrically connected to electrodes; and the device generates current flow in response to thermal change of outside.
